(19) United States
(12) Patent Application Publication
(10) Pub. No.: US 2025/0224185 A1
(43) Pub. Date: Jul. 10, 2025

(54) SWIRL-ENHANCED MICROCHANNEL COLD PLATE

(71) Applicant: STRATEGIC THERMAL LABS, LLC, GEORGETOWN, TX (US)

(72) Inventor: AUSTIN MICHAEL SHELNUTT, GEORGETOWN, TX (US)

(21) Appl. No.: 18/404,801

(22) Filed: Jan. 4, 2024

(51) Int. Cl. F28F 3/02; F28F 3/04; F28F 13/00; F28F 13/18; H05K 7/20

(52) U.S. Cl. CPC F28F 3/025; F28F 3/042; H05K 7/20827; F28F 2013/006; F28F 13/18; F28F 2245/04; F28F 2255/143; F28F 2260/02; F28F 2265/02

(57) ABSTRACT

A cold plate assembly includes a cold plate manufactured from a thermally conductive material and having a first surface attachable to a heat generating electronic component and a second surface opposite to the first surface, the second surface having an array of extended fins. A swirl enhancement plate of the cold plate assembly is positioned proximate and parallel to the second surface, having at least one nozzle opening to channel one or more corresponding impingement jets of cooling liquid toward the second surface, and having a plurality of swirl enhancement protrusions each extending toward the second surface in a corresponding microchannel between two adjacent extended fins to induce swirl/turbulence that disrupts a thermal boundary layer of the cooling liquid flow. An encapsulating lid attachable to the second surface forms a liquid cooling cavity encompassing the array of extended fins and swirl enhancement plate and includes intake and exhaust ports.

### BACKGROUND

### 1. Technical Field

The present application relates generally to heat transfer mechanisms used for cooling electronic devices, and more particularly, to liquid cooling apparatuses for removing heat generated by one or more electronic devices.

### 2. Description of the Related Art

Recent trends in global digital transformation have created incredible demand for increased processing performance in colocation and edge deployments of data/information processing servers. Datacenters today rely upon high power microprocessor devices, such as central processors (CPUs) and graphic processing units (GPUs), which generate a high level of heat in a small area. Traditional use of air as the heat transfer medium to cool heat dissipating components is unable to meet the thermal dissipation requirement of these high-power microprocessor devices. Thus, liquid cooling using cold plates have become a preferred way to provide the required cooling. Cold plates are a type of heatsink that allows for a cooling liquid to be brought into thermal conduction contact with the heat generating electronic components of servers and other information processing systems. These cold plates rely upon ultra-narrow fluid passages called “microchannels” to dissipate heat from the processors into the cooling liquid.

One challenge of constructing cold plates is that, unlike air-cooled heatsinks, cooling liquids have extremely high heat transfer coefficients that create diminished returns on fin height (commonly referred to as fin efficiency) because it is difficult to conduct heat through narrow passages using conventional metals. Fin efficiency limits typically result in cold plate fin heights that are less than 4 mm. This means that cold plates are effectively a two-dimensional heat sink receiving a single directional flow of cooling liquid over the fins.

### BRIEF DESCRIPTION OF THE DRAWINGS

The description of the illustrative embodiments can be read in conjunction with the accompanying figures. It will be appreciated that for simplicity and clarity of illustration, elements illustrated in the figures have not necessarily been drawn to scale. For example, the dimensions of some of the elements are exaggerated relative to other elements. Embodiments incorporating teachings of the present disclosure are shown and described with respect to the figures presented herein, in which:

FIG. 1 presents a three-dimensional disassembled view of an example cold plate assembly, which includes a swirl enhancement plate, and positioned for attachment to a heat generating electronic component, according to one or more embodiments;

FIG. 2 is a close up three-dimensional disassembled view of the cold plate assembly of FIG. 1, according to one or more embodiments;

FIG. 3 is a three-dimensional view of a lower surface of the swirl enhancement plate having swirl enhancement protrusions shaped as tapered rectangular turbulence posts, according to one or more embodiments;

FIG. 4 is a three-dimensional view of a top surface of swirl enhancement plate installed on a second surface of the cold plate, according to one or more embodiments;

FIG. 5 is a top view of an encapsulating lid channeling coolant liquid flows within a cooling liquid cavity to liquid cool the cold plate of FIG. 1, according to one or more embodiments;

FIG. 6 is a three-dimensional cut view of the cold plate presenting one elongated fin and an adjacent microchannel with computational fluid dynamics imagery of temperature and flow rates of cooling liquid affected by the swirl enhancement protrusions of the swirl enhancement plate, according to one or more embodiments;

FIG. 7 is a three-dimensional view of the second surface of the cold plate having total flow rate vector imagery for split flow orientation, according to one or more embodiments;

FIG. 8 is a top horizontal cut view of the swirl enhancement plate on one side of nozzle opening(s) and the cold plate to present imagery of flow rate of cooling liquid in microchannels of the second surface affected by the swirl enhancement protrusions, according to one or more embodiments;

FIG. 9A is a three-dimensional vertical cut view of the swirl enhancement protrusions of the swirl enhancement plate projecting into a microchannel of the cold plate, with flow rate imagery of the cooling liquid as it flows interrupted by the swirl enhancement protrusions in the microchannel, according to one or more embodiments;

FIG. 9B is a three-dimensional vertical cut view of the swirl enhancement protrusions of the swirl enhancement plate of FIG. 9A with horizontal cut plot indicated in black and vertical cut plot indicating in dark gray, according to one or more embodiments;

FIG. 10 illustrates a physical vapor deposition (PVD) process for coating wetted surfaces of the example cold plate assembly of FIG. 1 with a protective coating, which protects the wetted surfaces from damage, deterioration, and/or clogging due to exposure to facility-grade cooling liquids, according to one or more embodiments;

FIG. 11 is a side view diagram of an information processing system including a heat generating electronic component with an attached cold plate assembly with the swirl enhancement plate to create high vorticity flow, according to one or more embodiments;

FIG. 12A-12B (collectively “FIG. 12”) are a flow diagram presenting a method of manufacturing a cold plate assembly for providing liquid cooling of heat generating electronic components, according to one or more embodiments;

FIG. 13 is a flow diagram presenting a method that augments the method of FIG. 12 to environmentally hardening wetted surfaces of the cold plate assembly that may be exposed to cooling liquid to enable utilizing facility liquid for liquid cooling of heat generating electronic components without experiencing issues of fouling or clogging, according to one or more embodiments; and

FIG. 14 is a flow diagram presenting a method of using a cold plate assembly to liquid cool heat generating components of an information processing system.

### DETAILED DESCRIPTION

According to a first aspect of the present disclosure, an encapsulated heatsink (“a cold plate assembly”) is configured for cooling heat generating electronic components with liquid coolant that flows around inserted channel obstructions, which generates swirling, resulting in high vorticity flow and increased heat absorption. In one or more embodiments, a cold plate of the cold plate assembly has a conductive substrate with extended fin features providing microchannels of narrow hydraulic diameter that is enhanced for more efficiently liquid cooling with implementation of a swirl enhancing manifold solution. The swirl enhancing manifold solution is provided by a swirl enhancement plate having geometrically optimized posts that extend into the liquid flow path of each microchannel to create high vorticity flow. This high vorticity flow disrupts the thermal boundary layer growth on each surface, which, in turn, induces a significantly larger convection heat transfer coefficient than laminar flow typically observed in microchannel cold plates. In one or more embodiments, the swirl enhancing manifold solution also includes jet impingement nozzles that create high velocity and high heat transfer coefficient convection flows on the heated surfaces of the cold plate impinged by the incoming flow of cooling liquid.

In one or more embodiments, the cold plate assembly includes a cold plate manufactured from a thermally conductive material and having a first surface attachable to a heat generating electronic component. The cold plate has a second surface having an array of extended fins. The second surface is opposite to the first surface. A swirl enhancement plate of the cold plate assembly is positioned as a first layer proximate and parallel to the second surface. The swirl enhancement plate has at least one nozzle opening to channel one or more corresponding impingement nozzle jets of cooling liquid toward the second surface. The swirl enhancement plate has a plurality of swirl enhancement protrusions each extending toward the second surface in a corresponding microchannel between two adjacent extended fins of the array of extended fins. The swirl enhancement protrusions induce the swirl or turbulence to cooling liquid flow between the adjacent extended fins. The swirl or turbulence induced in the cooling liquid flow disrupts a thermal boundary layer of the cooling liquid flow, resulting in increased liquid heat transfer at the second surface. An encapsulating lid of the cold plate assembly is attachable to the second surface to form a liquid cooling cavity encompassing the array of extended fins and swirl enhancement plate. The encapsulating lid includes an intake port for receiving the cooling liquid flow from a cooling liquid source. The encapsulating lid includes an exhaust port for receiving and expelling exhaust cooling liquid that has flowed across the second surface of the cold plate.

According to a second aspect of the present disclosure, an information processing system includes at least one heat generating electronic component and the above-introduced cold plate assembly thermally attached/connected to the at least one heat generating electronic component to provide liquid cooling. In a third aspect of the present disclosure, a data center includes an information processing system rack having an information processing system that includes at least one heat generating electronic component and the above-introduced cold plate assembly thermally attached/connected to the at least one heat generating electronic component to provide liquid cooling.

Future central processing units (CPUs) and application specific integrated circuits (ASICs) are pushing past the current boundaries of heat generation during information processing within an information processing system. While liquid cooling is the preferred method for addressing the high thermal yields of these devices, the standard fin geometries of conventional cold plates have a limited surface area in a relative 2-dimensional (2D) space and thus cannot provide sufficient cooling for these devices as the devices increase their thermal output. Creating larger surface area on a conventional 2D cold plate, geometrically requires creating ever smaller and smaller fin spacings. Current technology allows manufacturers to create 0.2-0.4 mm channels which, while ideal for 2D heat transfer, are very intolerant of debris, particles, and corrosion agents within the cooling liquid, necessitating specialized water quality control via secondary coolant loop (i.e., technology cooling system (TCS)). Also, as the cooling liquid flows from an intake side of the microchannels to the exhaust side, thermal boundaries are created at the surface of the cooling liquid, which results in less efficient heat absorption towards the exhaust end of the microchannel. As a result, more cooling liquid flow is required to complete the heat absorption at the exhaust end of the microchannel, with an imbalance in reduced heat absorption efficiency as the cooling liquid flows along the length of the microchannel. The limits of these conventional systems have been reached. The present disclosure addresses and overcomes these limitations in existing cold plate technology by providing a swirl plate enhancement to disrupt a thermal boundary layer of the cooling liquid at a surface of the cold plate. Additionally, in one or more embodiments, the present disclosure provides more efficient heat transfer and thermal dissipation from the attached heat generating electronic component by providing phase change heat transfer using a saturated working fluid within a phase change cavity (“vapor chamber”) placed between the heat generating electronic component and the bottom surface of the attached cold plate. Alternatively, or in addition, the cold plate incorporates a vapor chamber. Accordingly, the cold plate assembly provides a more efficient heat exchange mechanism for use within a liquid cooling loop of a datacenter facility or other operating environment.

The present disclosure also overcomes deficiencies in the existing liquid cooling solutions caused by the sensitive nature of the convention cold plates, which are susceptible to corrosion and clogging if exposed to a flow of regular liquid. Specifically, one aspect of the present disclosure provides an environmentally hardened cold plate and a corresponding environmentally hardened cold plate assembly and liquid cooling system that are resistive to the fouling from direct exposure to facility water and thus enables the data center cooling solution to be provided with a single cooling loop utilizing the facility water supply.

In the following detailed description of exemplary embodiments of the disclosure, specific exemplary embodiments in which the various aspects of the disclosure may be practiced are described in sufficient detail to enable those skilled in the art to practice the invention, and it is to be understood that other embodiments may be utilized and that logical, architectural, programmatic, mechanical, electrical, and other changes may be made without departing from the spirit or scope of the present disclosure. The following detailed description is, therefore, not to be taken in a limiting sense, and the scope of the present disclosure is defined by the appended claims and equivalents thereof. Within the descriptions of the different views of the figures, similar elements can be provided with similar names and reference numerals as those of the previous figure(s). The specific numerals assigned to the elements are provided solely to aid in the description and are not meant to imply any limitations (structural or functional or otherwise) on the described embodiment. It will be appreciated that for simplicity and clarity of illustration, elements illustrated in the figures have not necessarily been drawn to scale. For example, the dimensions of some of the elements are exaggerated relative to other elements.

It is understood that the use of specific component, device and/or parameter names, such as those of the executing utility, logic, and/or firmware described herein, are for example only and not meant to imply any limitations on the described embodiments. The embodiments may thus be described with different nomenclature and/or terminology utilized to describe the components, devices, parameters, methods and/or functions herein, without limitation. References to any specific protocol or proprietary name in describing one or more elements, features or concepts of the embodiments are provided solely as examples of one implementation, and such references do not limit the extension of the claimed embodiments to embodiments in which different element, feature, protocol, or concept names are utilized. Thus, each term utilized herein is to be given its broadest interpretation given the context in which that term is utilized. As a specific example, reference is made herein to the term facility liquid, facility water, facility cooling liquid, facility-grade cooling liquid, and cooling liquid. It is appreciated that the terms facility liquid or facility cooling liquid are utilized to provide a specific example of a cooling liquid supplied by/at a datacenter facility in which the heat generating electronic components are operating and being cooled in a single liquid cooling loop that includes facility liquid, which is typically unpurified water. Facility-grade cooling liquid is a more general term that can apply to both cooling liquid that is being provided at a datacenter facility or any other cooling liquid that can contain contaminants and particulates, similar to the normal facility liquid found in datacenters. Thus, facility-grade cooling liquid can apply to any type of liquid, regardless of the source of the liquid, and can also apply to liquid cooling that is not provided at a “facility” or datacenter. The descriptions herein are meant to apply to any type of facility-grade cooling liquid. Additionally, it is appreciated that the cooling liquid utilized within the cooling loop that includes the described cold plate assembly can also be a higher-grade cooling liquid than facility-grade cooling liquid, without limitation.

As further described below, implementation of the functional features of the disclosure described herein is provided within processing devices and/or structures and can involve use of a combination of hardware, firmware, as well as several software-level constructs (e.g., program code and/or program instructions and/or pseudo-code) that execute to provide a specific utility for the device or a specific functional logic. The presented figures illustrate both hardware components and software and/or logic components.

Those of ordinary skill in the art will appreciate that the hardware components and basic configurations depicted in the figures may vary. The illustrative components are not intended to be exhaustive, but rather are representative to highlight essential components that are utilized to implement aspects of the described embodiments. For example, other devices/components may be used in addition to or in place of the hardware and/or firmware depicted. The depicted example is not meant to imply architectural or other limitations with respect to the presently described embodiments and/or the general invention. The description of the illustrative embodiments can be read in conjunction with the accompanying figures. Embodiments incorporating teachings of the present disclosure are shown and described with respect to the figures presented herein.

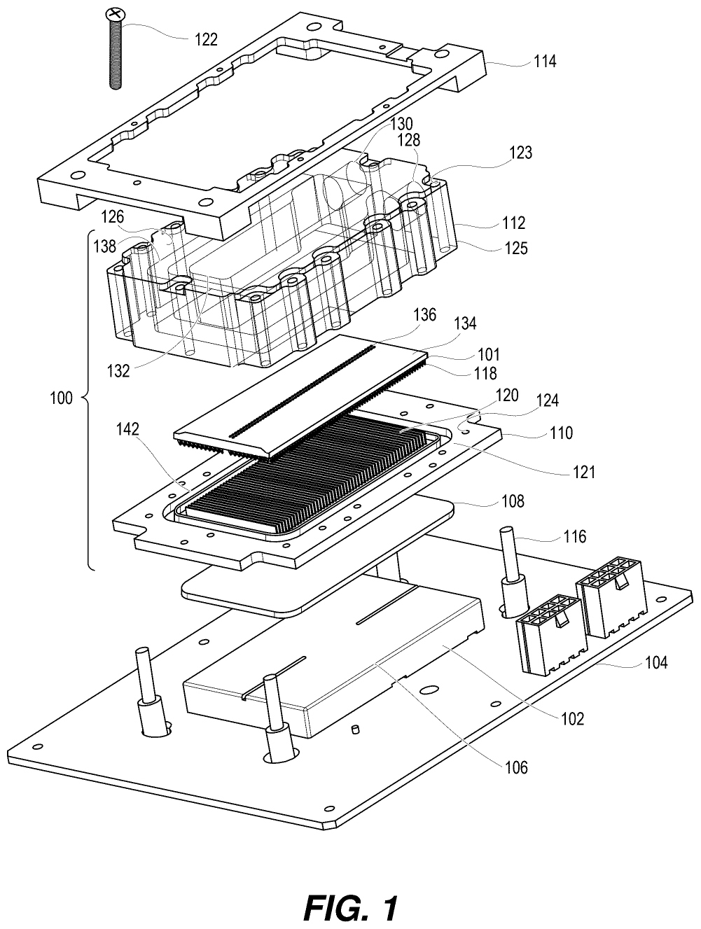

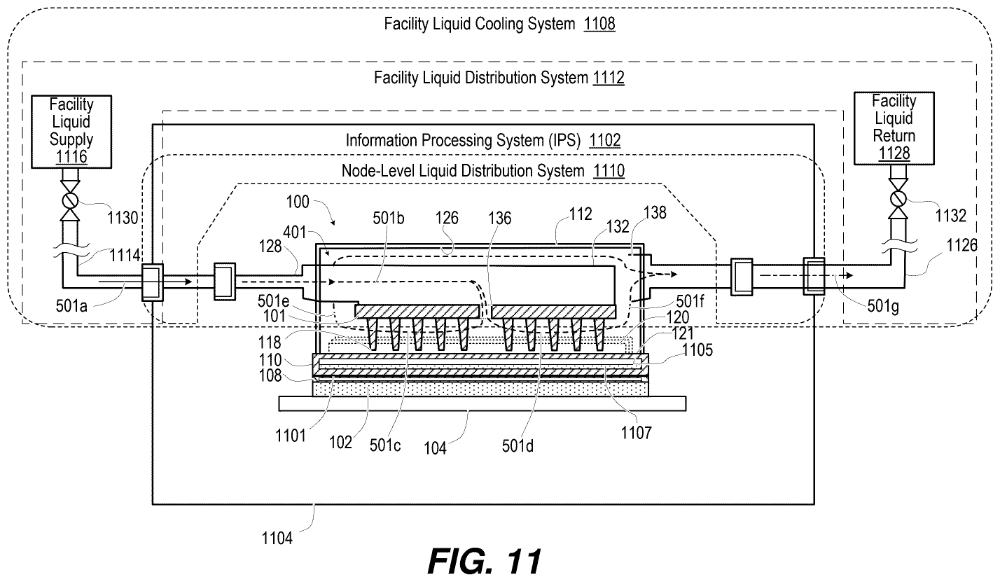

FIG. 1 presents a three-dimensional disassembled view of cold plate assembly 100, which includes swirl enhancement plate 101, for liquid cooling heat generating electronic component 102 on substrate 104. In an example, heat generating electronic component 102 includes central processing unit (CPU) integrated heat spreader 106 that is oriented toward cold plate assembly 100. In one or more embodiments, cold plate assembly 100 includes the following stacked components, referenced from closest to farthest away from heat generating electronic component 102: (i) optionally two-dimensional (2D) vapor chamber 108; (ii) cold plate 110; (iii) swirl enhancement plate 101; and (iv) encapsulating lid 112. First surface (see 1101, FIG. 11) of cold plate 110 is oriented toward heat generating electronic component 102. Optional 2D vapor chamber 108 is positionable between heat generating electronic component 102 and cold plate 110. Cold plate assembly 100 and optional 2D vapor chamber 108 are attached to heat generating electronic component 102 by cold plate retention plate 114 being engaged to locking pins 116 extending from substrate 104. Swirl enhancement plate 101 may be composed of at least one of a metal, a plastic or synthetic material and may be manufactured via an injection molding process.

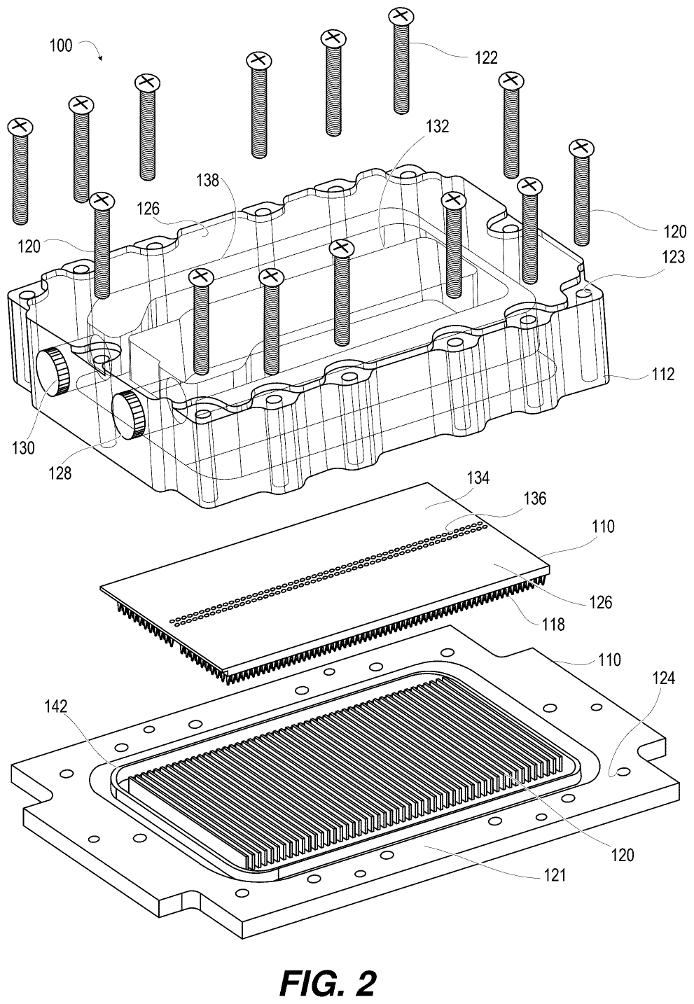

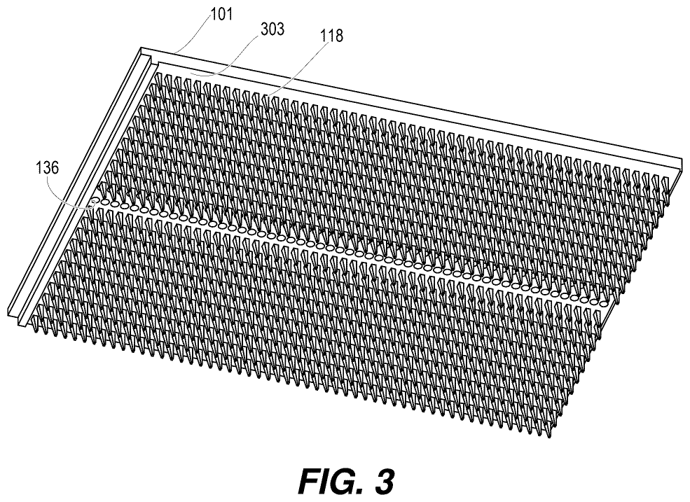

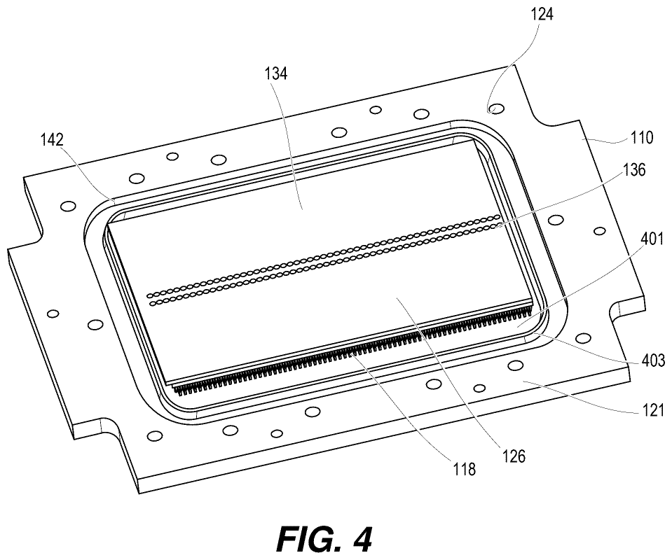

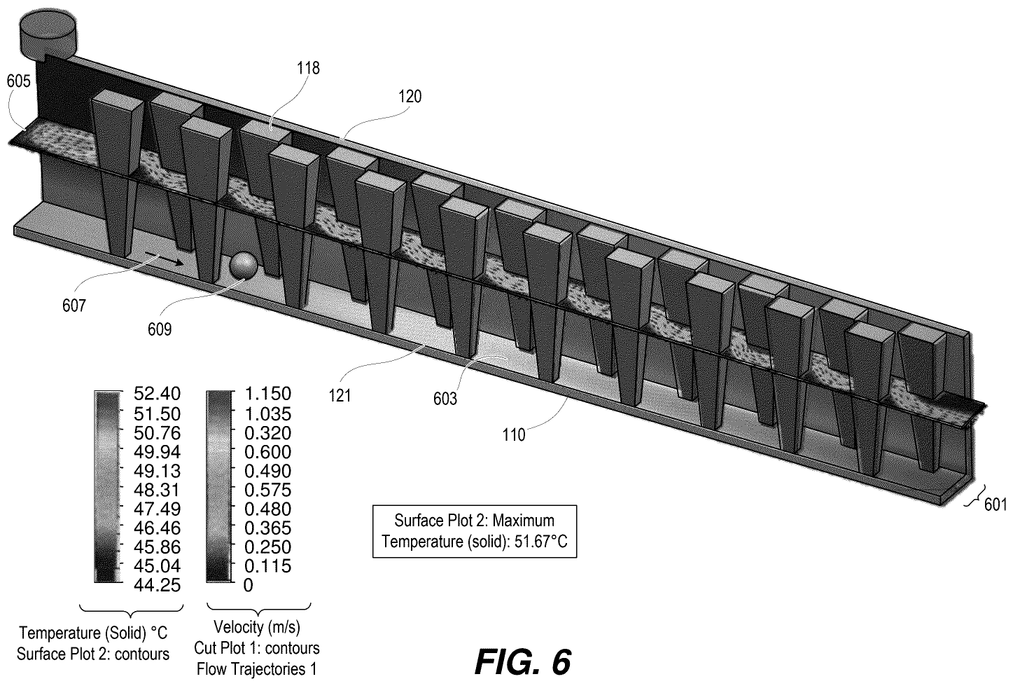

FIG. 2 is a close up three-dimensional disassembled view of cold plate assembly 100. With continuing reference to FIG. 1, cold plate assembly 100 includes swirl enhancement plate 101 between cold plate 110 and encapsulation lid 112. Swirl enhancement protrusions 118 extend from lower surface (see 303 of FIG. 3) of swirl enhancement plate 101 into the microchannels between the array of extended fins 120 on second surface 121 of cold plate 110. Cold plate assembly 100 is held together by threaded fasteners 122 that pass through peripheral through holes 123 of encapsulating lid 112 to be received in threaded holes 124 on second surface 121 of cold plate 110. Encapsulating lid 112 includes outer shell 125 that is attachable to second surface 121 to form liquid cooling cavity 126. Encapsulating lid 112 includes intake port 128 and exhaust port 130 through outer shell 125 that enable a flow of cooling liquid to enter and return from liquid cooling cavity 126. When cold plate assembly 100 is assembled, encapsulating lid 112 has intake manifold 132 that channels supply cooling liquid to a center portion of liquid cooling cavity 126 aligned with upper surface 134 and one or more nozzle openings 136 (e.g., one row of through holes, two parallel rows of through holes, or an elongate slot) of swirl enhancement plate 101. At least one row of nozzle opening(s) 136 or an elongated nozzle opening 136 of swirl enhancement plate 101 may be aligned orthogonal to the directional run of array of extended fins 120, providing cooling liquid flow to each respective microchannel (see 601 of FIG. 6) between extended fins 120. Encapsulating lid 112 has exhaust manifold 138, which is fluidly separated from intake manifold 132 and which channels exhaust cooling liquid from peripheral portion (see 401 of FIG. 4) of liquid cooling cavity 126 around swirl enhancement plate 101 to exhaust port 130.

Lateral dimensions of cold plate 110 may accommodate one or more than one heat generating electronic component 102 (FIG. 1). Cold plate 110 may be made of thermally conductive material such as copper facilitating heat transfer from attached heat generating electronic component 102 (FIG. 1) via a cooling liquid flow. Materials, including any treatments or coatings, of cold plate 110 are selected for compatibility and reliable use with the cooling liquid. In an example, the cooling liquid is water. In one or more embodiments, interior perimeter 142 of cold plate 110 is recessed at second surface 121 around the array of extended fins 120 to facilitate sealing attachment of encapsulating lid 112 to cold plate 110. Sealably attaching encapsulating lid 112 to cold plate 110 may include use of one or more of a press-fit interference attachment, an adhesive layer, soldering, brazing, welding, and a fastener attachment.

FIG. 3 presents a three-dimensional view of lower surface 303 of swirl enhancement plate 101 having swirl enhancement protrusions 118 shaped as tapered rectangular (or square) turbulence posts. Rectangular/square (i.e., angular) edges of the posts may enhance the creation of turbulent flow. The taper creates less of an obstruction closer to the second surface of the cold plate 110 (FIG. 1) allowing larger contaminate particles to pass by swirl enhancement protrusions 118 without clogging or restricting a flow of cooling liquid.

FIG. 4 presents a three-dimensional view of top surface of swirl enhancement plate 101 installed on second surface 121 of cold plate 110. Interior perimeter 142 of cold plate 110 is separated from peripheral portion 401 of cold plate 110 by rounded rectangular ridge 403 inside of which the perimeter of the encapsulating lid can be placed to facilitate a sealed impervious and leak proof attachment boundary.

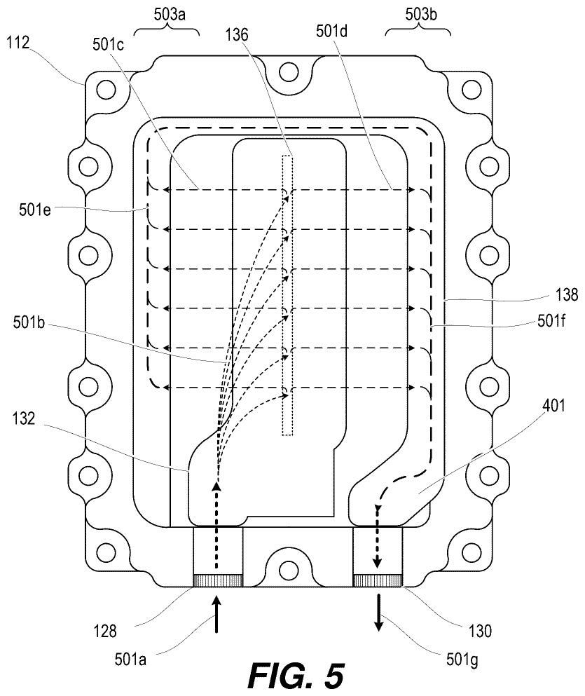

FIG. 5 presents a top transparent view of encapsulating lid, showing directional channeling of coolant liquid flows within cooling liquid cavity 126 of encapsulating lid 112 to liquid cool cold plate 110 (FIG. 1). Cooling liquid supply 501a enters intake port 128 of encapsulating lid 112. Intake manifold 132 channels distributed supply cooling liquid 501b to one or more nozzle opening 136 of swirl enhancement plate 101 (FIG. 1). In an example, nozzle opening 136 is centrally aligned, creating lateral split flows 501c-501d that move in opposite directions along the microchannels. Lateral split flow 501c as depicted moves to the left into beginning portion 503a of exhaust manifold 138 to start clockwise flow 501e around peripheral portion 401 of liquid cooling cavity 126. Lateral split flow 501d as depicted moves to the right into ending portion 503b of exhaust manifold 138 to join clockwise flow 501f, and the combined flows exit from exhaust port 130 as heated cooling liquid 501g. It is appreciated that the use of two centrally located arrays of nozzle openings is one embodiment for supplying the cooling liquid to the cold plate. Other methods can also provide that the intake port provide the cooling liquid to a first lateral side of the array of fins, where the cooling liquid is channeled from a first side of the microchannels around the swirl enhancement protrusions 118 to the second, opposite side of the microchannels at which the exhaust cooling liquid is collected and sent to the exhaust port. It is appreciated that the use of two centrally located arrays of nozzle openings is one embodiment for supplying the cooling liquid to the cold plate. Other methods can also provide that the intake port provide the cooling liquid to a first lateral side of the array of fins, where the cooling liquid is channeled from a first side of the microchannels around the swirl enhancement protrusions 118 to the second, opposite side of the microchannels at which the exhaust cooling liquid is collected and sent to the exhaust port.

FIG. 6 provides a three-dimensional cut view of cold plate 110 presenting one elongated fin 120 and adjacent microchannel 601 with computational fluid dynamics imagery of temperature (i.e., surface plot 603 superimposed on second surface 121 of cold plate 110) and flow rates (i.e., cut plot 605) of cooling liquid affected by swirl enhancement protrusions 118 of swirl enhancement plate 101. As depicted by arrow 607, cooling liquid flows left to right becoming progressively warmer as surface plot 603 superimposed on second surface 121 of cold plate 110 indicates. Swirl enhancement protrusions 118 cause the cooling liquid to swirl, resulting in high vorticity flow and increased heat absorption. As also shown, the distal tapering of swirl enhancement protrusions 118 allows contaminate particles 609 to pass through without clogging microchannel 601.

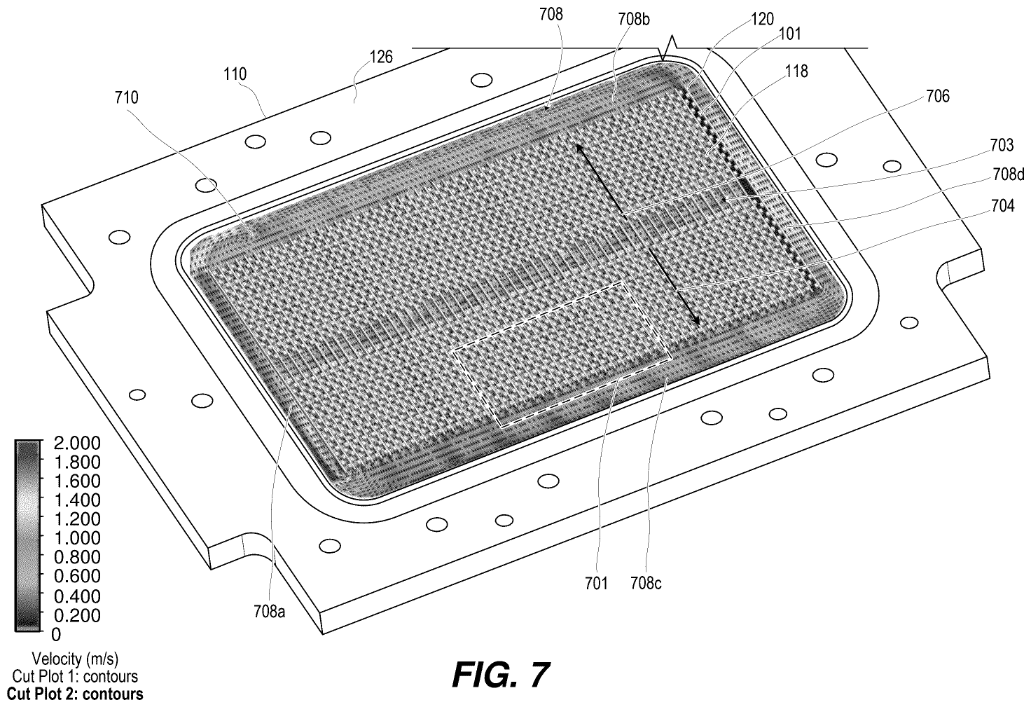

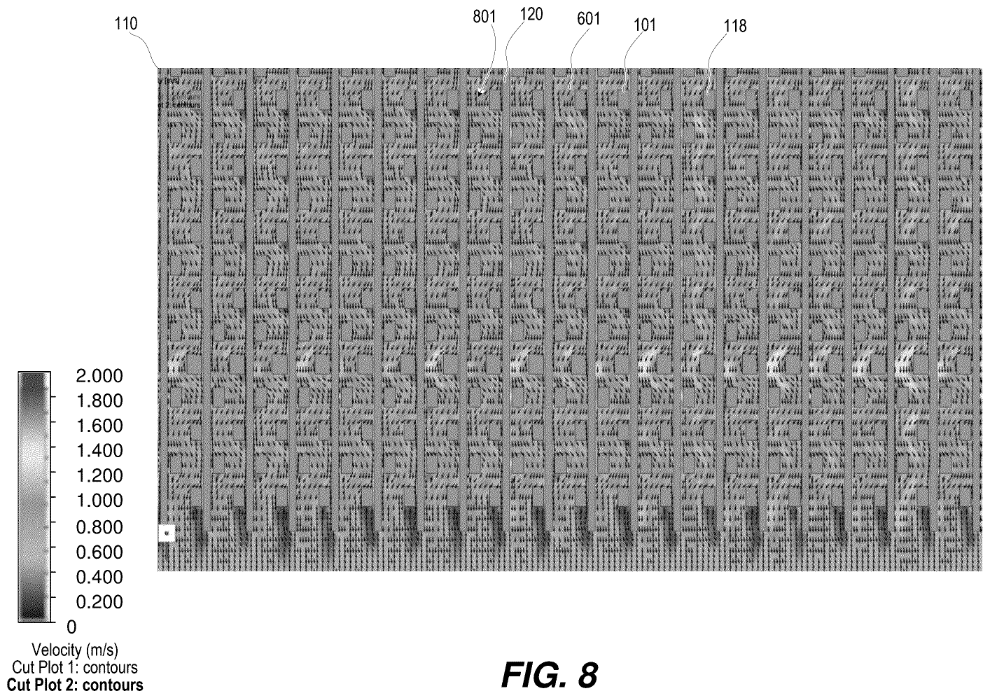

FIG. 7 provides a three-dimensional view of second surface 121 of cold plate 110 with swirl enhancement protrusions 118 creating swirl or turbulence in total flow rate vector imagery for “split flow”. Box 701 indicates an area of cold plate 110 and swirl enhancement protrusions 118. FIG. 8 provides a close up, top horizontal cut view of box 701 (FIG. 7) of swirl enhancement protrusions 118 of swirl enhancement plate 101 extended into microchannels 601 of second surface 121 of cold plate 110 to present flow rate imagery of cooling liquid affected by swirl enhancement protrusions 118. With particular reference to FIG. 7, in one or more embodiments, “split flow” of supply cooling liquid is provided by directing supply cooling liquid to centerline 703 of cold plate 110. Supply cooling liquid splits into two opposite flow directions, as depicted by arrows 704-706, away from centerline 703 of cold plate 110 at a uniform flow rate. Flow rate of cooling liquid that reaches periphery 708 outside of the array of extended fins 120 varies in flow rate as indicated by having different colored imagery. The simulation model used for computation fluid dynamics (CFD) to generate the flow vector imagery differed from cold plate assembly 100 of FIG. 1 in that the peripheral flow completely circles swirl enhancement plate 101, creating a high flow rate along bottom periphery 708a. All of the exhaust cooling liquid from bottom periphery 708a and left periphery 708b converges at return point 710 of left periphery 708b proximate to bottom periphery 708a. Some of the exhaust cooling liquid flow from right periphery 708c flows through bottom periphery 708a. A remainder of the exhaust cooling liquid flow from right periphery 708c flows through top periphery 708d to left periphery 708b. Arrows 801 indicate lateral swirl or turbulence alternating back and forth between adjacent extended fins 120. With the flow dynamics presented by FIG. 7, the swirl or turbulence induced in the cooling liquid flow increases convective cooling of extended fins 120.

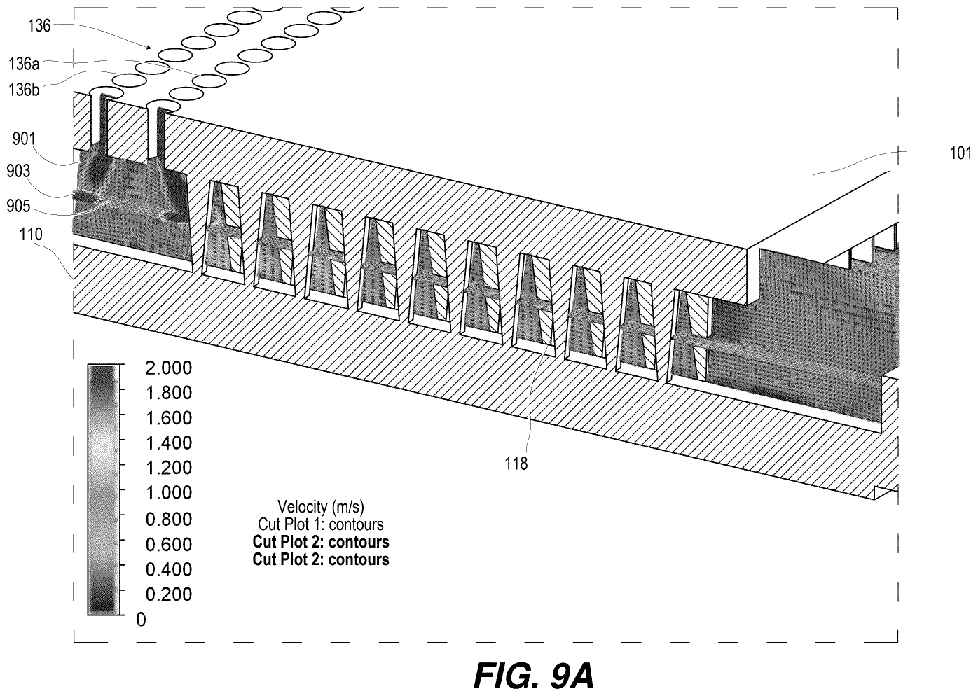

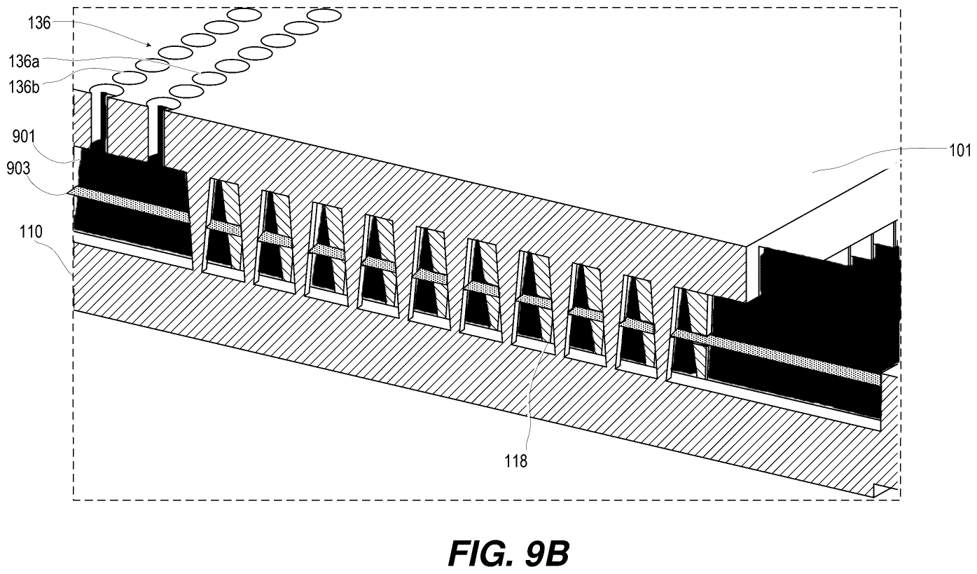

FIG. 9A provides a three-dimensional vertical cut view of a right half of swirl enhancement plate 101 with swirl enhancement protrusions 118 extended into microchannel 601 of second surface 121 of cold plate 110, presenting flow rate imagery (i.e., vertical cut plot 901 and horizontal cut plot 903) of cooling liquid in microchannel 601. For clarity, FIG. 9B is a three-dimensional vertical cut view of a right half of swirl enhancement plate 101 with swirl enhancement protrusions 118 extended into microchannel 601 of second surface 121 of cold plate 110, with only the shape of vertical cut plot 901 indicated in black. The shape of horizontal cut plot 903 orthogonally extends from vertical cut plot 901 and is indicated in dark gray. With particular reference to FIG. 9A, one or more nozzle openings 136 are provided by a sequence of right nozzle openings 136a aligned with a sequence of left nozzle openings 136b. High flow rate received at one or more right nozzle openings 136a located at a midpoint of the top surface plate of swirl enhancement plate 101 is slowed and made more turbulent by swirl enhancement protrusions 118. Left half of cold plate assembly 100 has a similar configuration as right half and receives the flow of cooling liquid from the left sequence of nozzle openings 136b. Vertical cut plot 901 indicates a color change of a slower flow rate at the top where swirl enhancement protrusions 118 are wider to a faster flow rate at the bottom where swirl enhancement protrusions 118 are tapered to a narrower obstruction. Arrows 905 and flow rate colors of horizontal cut plot 903 indicate slower flow on a downstream side of each swirl enhancement protrusions 118 with the lateral side-to-side turbulence flow around each swirl enhancement protrusions 118.

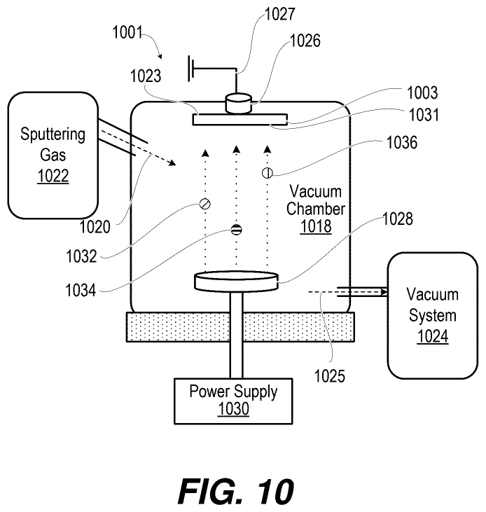

FIG. 10 illustrates a physical vapor deposition (PVD) apparatus 1001 that performs a process for coating wetted surfaces of liquid cooling components 1003 of cold plate assembly 100 of FIG. 1 with a protective coating that protects the wetted (interior) surfaces of cold plate assembly 100 from damage, deterioration, and/or clogging due to exposure to facility-grade cooling liquids. Unlike conventional devices, environmentally hardened liquid cooling components 1003 of cold plate assembly 100, with a protective surface coating, are tolerant of poorly controlled water quality (including from both chemical contaminants and particulates). Examples of liquid cooling component 1003 include swirl enhancement protrusions 118 of swirl enhancement plate 101, cold plate 110, and liquid cooling cavity 126 of encapsulating lid 112 (FIG. 1).

To facilitate use of a facility cooling liquid, such as unpurified water, liquid cooling component 1003 is environmentally hardened, such as by applying a coating in physical vapor deposition (PVD) apparatus 1001. PVD apparatus 1001 includes three-dimensional (3D) vapor chamber 1018 that is filled with sputtering gas 1020 received from sputtering gas supply 1022 and that is maintained at an appropriate pressure by vacuum system 1024 that removes excess gas 1025. Upward oriented surface 1023 of liquid cooling component 1003 is engaged to substrate holder 1026, which is connected to electrical ground 1027. Downward oriented surface 1031 of liquid cooling component 1003 is oriented toward target 1028, which includes one or more coating materials to be deposited onto downward oriented surface 1031 of liquid cooling component 1003 by PVD. Target 1028 is connected to power supply 1030 to cause ionization of sputtered atoms 1032, 1034, and 1036, which are attracted by the voltage difference between target 1028 and liquid cooling component 1003 to that transit across vacuum chamber 1018 and be deposited onto downward oriented surface 1031 of liquid cooling component 1003 to form a protective coating. In an example, first atom 1032 represents a hydrophobic material, second atom 1034 represents a non-conductive material, and third atom 1036 represents an anti-corrosive material. Wetted surfaces cold plate 110 are coated with non-conductive, anti-corrosion surface enhancements such as Zirconium Nitride, Titanium Nitride, and other ceramics applied by PVD. In one or more embodiments, the surface may also be coated with a hydrophobic surface treatment to mitigate scale and sedimentation. The specific description of PVD as the process is thus not intended to be limiting on the scope of the disclosure. To coat all wetted surface of liquid cooling component 1003, liquid cooling component 1003 may be processed by PVD while in more than one orientation so that each wetted surface is coated.

It is appreciated that while the coating process is shown to be completed by PVD, other similar techniques can be utilized to provide the coating layer(s) on the first surface of cold plate to yield the various physical and chemical enhancements that are described herein. In an example, liquid cooling component 1003 or an assembly of liquid cooling components 1003 may be dipped or immersed into liquid that provides the surface treatment.

Facility water, which may contain corrosive chemical and particulate contaminants would be suboptimal for liquid cooling using conventional cold plates. In one or more embodiments, the protective coating applied to the cold plate by the above-described PVD process provides one or more protective characteristics, including: (i) a hydrophobic characteristic to mitigate scaling by calcium carbonate, (ii) an anti-corrosive characteristic to mitigate formation corrosion, and (iii) a non-conductive characteristic to mitigate rusting. Cold plate assembly 100 covered at least in part with the resulting coating is designed to resist heat transfer inhibiting failure modes common to liquid cooling with poorly regulated water quality, namely suspended solid particulates, biological growth potential, and harsh water chemistry conditions, including semi-corrosive mixtures.

FIG. 11 illustrates an example information processing system (IPS) 1102 including heat generating electronic component 102 on substrate 104 with integrated heat spreader 106 attached to first surface 1101 of cold plate assembly 100. Facility liquid cooling system 1108 provides liquid cooling to node enclosure 1104 within which the IPS 1102 is located. In the presented embodiment, cold plate 110 of cold plate assembly 100 includes integral vapor chamber 1105 containing working fluid 1107 and extending from a base (first) surface of cold plate 110, with the other, opposed surface of vapor chamber 1105 in thermal connection with integrated heat spreader 106 of the heat generating electronic component 102 of IPS 1102. In one or more embodiments, cold plate assembly 100 also includes or is attached to 2D vapor chamber 108. In one or more alternate embodiments, cold plate assembly 100 includes a solid cold plate 110 that does not have an integral vapor chamber and can either not include 2D vapor chamber 108 or include 2D vapor chamber 108. In one or more additional embodiments, cold plate assembly 100 has cold plate 110 with integral vapor chamber 1105 and does not include 2D vapor chamber 108. In one or more embodiments, cold plate assembly 100 has a solid cold plate 110 without an integral vapor chamber but does include 2D vapor chamber 108.

In one or more embodiments, as shown by FIG. 11, intake port 128 and exhaust port 130 may be positioned on opposite lateral sides of cold plate assembly 100. In one or more embodiments, intake port 128 and exhaust port 130 may be positioned on adjacent lateral sides. In one or more embodiments, intake port 128 and exhaust port 130 may be positioned on the same lateral side. In one or more embodiments, intake port 128 and exhaust port 130 may both be positioned on the top side. In one or more embodiments, intake port 128 and exhaust port 130 may be positioned respectively on the top side and one lateral side.

Cooling liquid supply 501a enters intake port 128 of encapsulating lid 112. Intake manifold 132 channels distributed supply cooling liquid 501b to one or more nozzle opening 136 of swirl enhancement plate 101. In an example, nozzle opening 136 is centrally aligned, creating lateral split flows 501c-501d that move in opposite directions. As depicted, lateral split flow 501c moves to the left into beginning portion 503a of exhaust manifold 138 to start clockwise flow 501e around peripheral portion 401 of liquid cooling cavity 126. As also depicted, lateral split flow 501d moves to the right into ending portion 503b of exhaust manifold 138 to join clockwise flow 501f to exit from exhaust port 130 as heated cooling liquid 501g.

IPS 1102 includes one or more heat generating electronic component(s), presented as example heat generating electronic component 102 (FIG. 1). Liquid cooling system 1108 provides cooling liquid flow to cold plate assembly 100 to cool one or more heat generating electronic component 102. Liquid cooling system 1108 includes node-level liquid distribution system 1110 within node enclosure 1104 and is part of IPS 1102. Liquid cooling system 1108 includes rack level and/or data center level liquid distribution system, which are external to IPS 1102 and node enclosure 1104. For simplicity, rack level and/or data center level liquid distribution system will collectively be referred to as facility liquid distribution system 1112 to distinguish from the node-level liquid distribution system 1110. Facility liquid distribution system 1112 includes supply distribution conduit 1114 sealably coupled to facility liquid supply 1116 via intake port 128 for liquid transfer to provide unheated facility liquid, such as water, to intake port 128 of node-level liquid distribution system 1110. Exhaust port 130 of node-level liquid distribution system 1110 returns heated cooling liquid 501g that has passed through cold plate assembly 100. Facility liquid distribution system 1112 includes return distribution conduit 1126 sealably coupled to exhaust port 130 for liquid transfer to facility liquid return 1128. Encapsulating lid 112 is configured to sealably couple for fluid flow via liquid conduits (i.e., node-level liquid distribution system 1110 and facility liquid distribution system 1112) from facility liquid supply 1116 and to facility liquid return 1128. Liquid flow through liquid cooling system 1108 may be controlled by a binary or proportional electrically actuated supply valve 1130 that is incorporated into supply distribution conduit 1114. Alternatively, or in addition, liquid flow through liquid cooling system 1108 may be controlled by a binary or proportional electrically actuated return valve 1132 that is incorporated into return distribution conduit 1126.

Aspects of the present disclosure may be applied to an edge mobile datacenter or facility with a single rack IPS. Additionally, aspects of the present disclosure may also be applied to an enterprise datacenter having multiple buildings and rooms with tens, hundreds, or thousands of rack IPSes. In one or more embodiments, a facility source of facility-grade cooling liquid may include a facility outlet port and a facility return port. A first branch of liquid distribution system may be sealably connected between the intake port of the cold plate assembly and an outlet port of the facility source to channel unheated facility water to the cold plate assembly, and a return branch of liquid distribution system may be sealably connected between the exhaust port of the cold plate assembly and the facility return port to channel heated exhaust water from the cold plate assembly to the facility return port.

In one or more embodiments, the liquid distribution system includes a rack liquid cooling manifold system with a supply manifold and a return manifold. The supply manifold includes a supply control valve and a manifold intake port available for sealably coupling to a facility water supply to receive a cooling liquid. The supply manifold includes more than one server supply ports. Each server supply port is available for sealably coupling, for liquid transfer of the cooling liquid, to a respective cooling liquid supply input of a corresponding information processing system node supported by a rack frame capable of supporting multiple information processing system nodes.

Each information processing system node has one or more heat generating electronic component. The return manifold includes a facility water return port for sealably coupling to a facility return to exhaust the cooling liquid. The return manifold includes more than one server return ports. Each server return port is available for sealably coupling, for exhaust liquid transfer, to a respective cooling liquid exhaust output of the corresponding information processing system node. The respective cooling liquid exhaust output and a paired supply liquid cooling input directs cooling liquid flow through one or more cold plate assembly positioned within the corresponding information processing system node to thermally cool the one or more heat generating electronic components.

In one or more particular embodiments, the liquid distribution system further includes a plurality of conduits that sealably couple for liquid transfer: (i) the more than one server supply ports of the supply manifold to the corresponding server supply inputs of the more than one information processing system nodes; (ii) the corresponding server supply input to the one or more cold plate assemblies in the corresponding information processing system node; (iii) the one or more cold plate assemblies in the corresponding information processing system node to the corresponding server return output; and (iv) the more than one server return outputs to the server return ports of the return manifold.

IPS 1102 may be located in a node of an information processing system rack of a datacenter equipment center with rack-level liquid cooling of heat generating electronic components, each utilizing an attached one of the cold plate assembly 100 of FIG. 1, and utilizing one liquid cooling loop for heat exchange, according to one or more embodiments. The datacenter equipment center may be within a building that includes multiple rack information processing systems (IPSes) that have respective information processing systems (IPSes), which receive liquid cooling by respective ones of cold plate assembly 100. In one or more embodiments, a rack IPSes is supported by a floor filtration unit (FFU) in a floor space of the datacenter equipment center. Alternatively, or in addition, rack IPSes may be supported by rack filtration units (RFUs). Liquid cooling system may include a single liquid cooling loop, facility cooling liquid system (FCLS). FCLS circulates facility liquid from a cooling tower (or a facility supply) through conduits to the data center and IPSes in the multiple rack IPSes and from each cold plate back to the cooling tower (or facility return) to dissipate thermal energy to ambient air. Utilization of cold plate assemblies provides liquid cooling of heat generating components within the data equipment center, which may eliminate the need for use of purified liquid in a separated rack level technology cooling system and the multiple separated cooling loops to provide reliable operation of a liquid cooling system.

Aspects of the present disclosure may be applied to multiple cooling loop systems. In an example, a liquid cooling system may include four isolated liquid cooling loops in series, a technology cooling system (TCS), a facility cooling liquid system (FCLS), and a condenser liquid system that support rack IPSes. A chiller loop may be counted as an additional liquid cooling loop. TCS is supported by a cooling distribution unit (CDU) that circulates cooling liquid through an IPS via a closed loop. CDU transfers thermal energy from the TCSs to facility cooling liquid such as unpurified water provided by a facility cooling system (FCLS). In an example, FCLS may transfer exhaust thermal energy directly into ambient air via a cooling tower. The liquid cooling system may further include a condenser liquid system (CLS) that circulates cooling water through the cooling tower. The liquid cooling system may further include the chiller loop (or chiller) that stores a thermal buffering quantity of liquid such as water. The chiller circulates the water through a first liquid-to-liquid heat exchanger to receive thermal energy from FCLS. The chiller circulates the heated water through a second liquid-to-liquid heat exchanger to transfer thermal energy to the CLS. The chiller enables intermittent use of the cooling tower while maintaining water in the chiller within a temperature range suitable for both FCLS and CLS.

Utilization of a cold plate assembly to provide liquid cooling of heat generating components within the data center eliminates the need for use of purified liquid in a separated rack level technology cooling system and the multiple separated cooling loops to provide reliable operation of the liquid cooling system. An existing data center cooling system can be retrofitted with IPSes that are configured with a plurality of a cold plate assembly as the mechanism for colling the heat generating components within the IPS racks and replace the more expensive purified cooling liquids within the technology cooling system loop, without having issues related to fouling of the cold plates with the switch to utilizing normal, facility rated liquid supply.

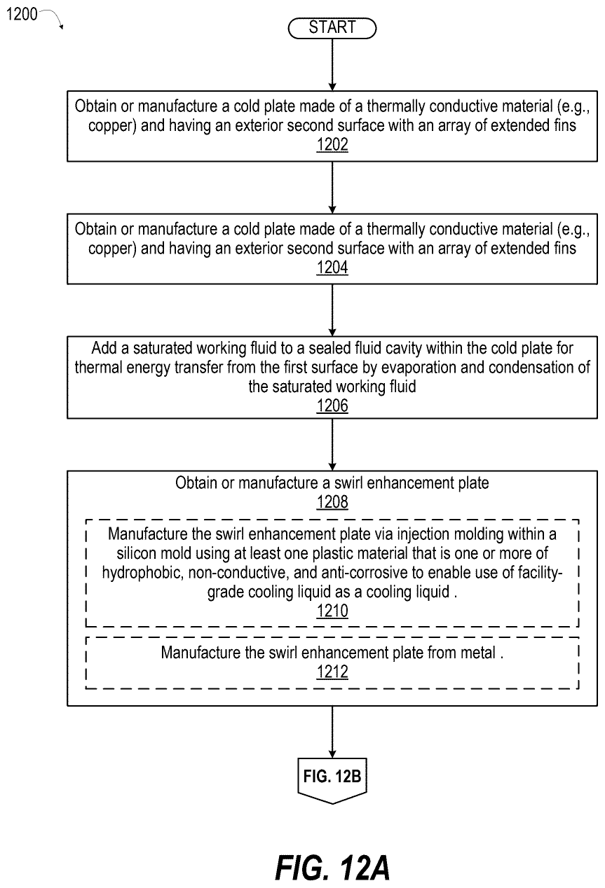

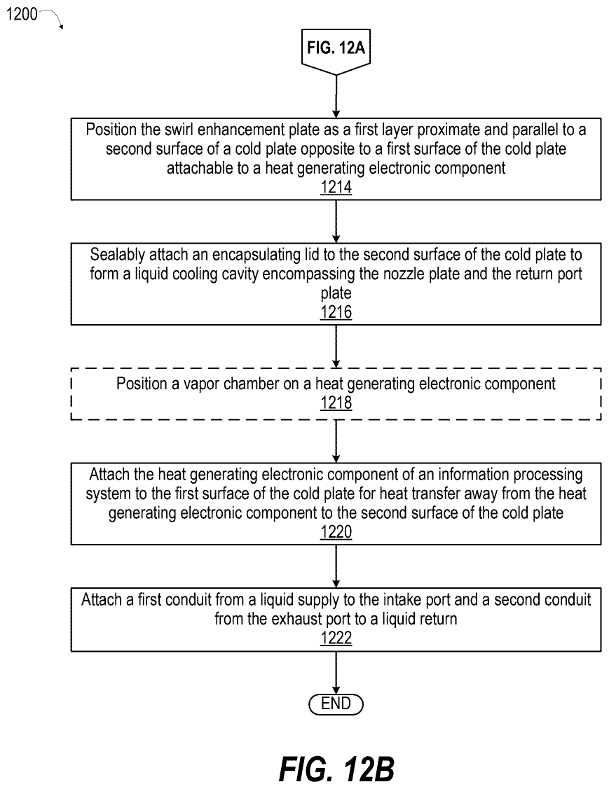

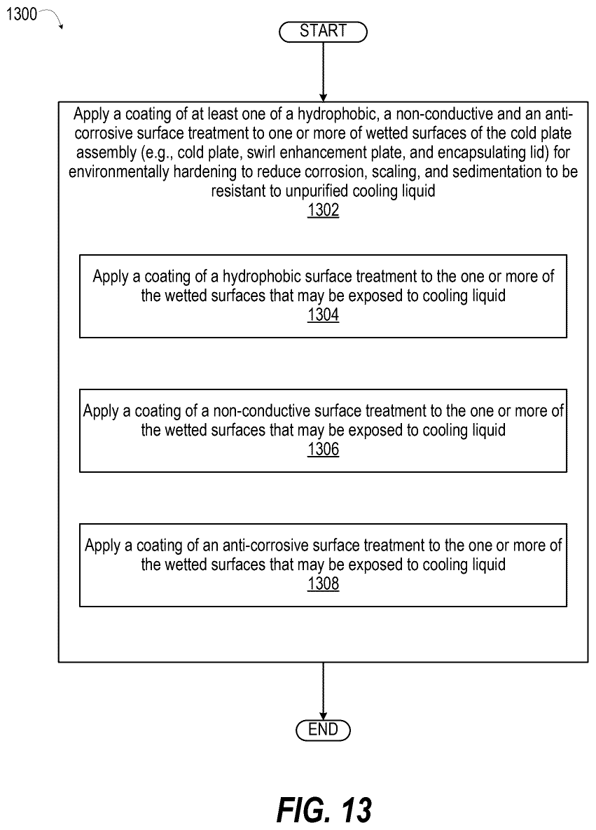

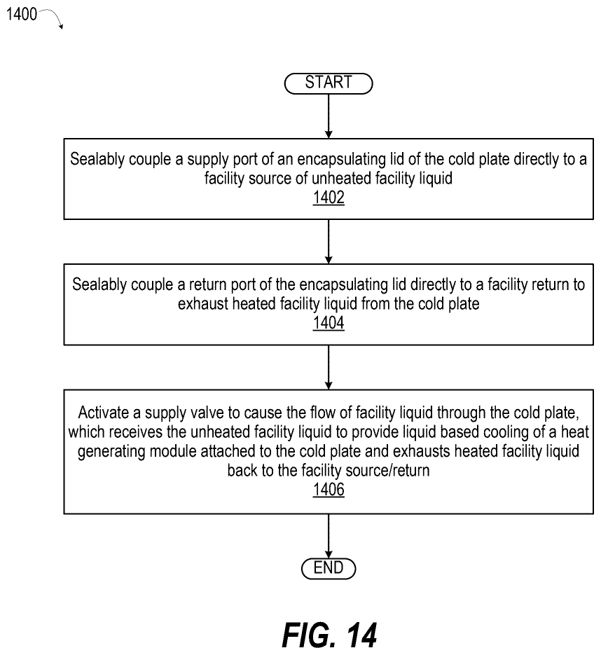

FIG. 12A-12B (collectively “FIG. 12”) are a flow diagram presenting method 1200 of manufacturing a cold plate assembly for providing liquid cooling of heat generating electronic components. FIG. 13 is a flow diagram presenting method 1300 that augments method 1200 (FIG. 12) by environmentally hardening wetted surfaces of the cold plate assembly that may be exposed to cooling liquid to enable utilizing facility liquid for liquid cooling of heat generating electronic components, without experiencing issues of fouling or clogging. FIG. 14 is a flow diagram presenting method 1400 of using a cold plate assembly to liquid cool heat generating components of an information processing system. The descriptions of method 1200 (FIG. 12), method 1300 (FIG. 13) and method 1400 (FIG. 14) are provided with general reference to the specific components illustrated within the preceding FIGS. 1-8, 9A-9B, and 10-11. Specific components referenced in method 1200 (FIG. 12), method 1300 (FIG. 13) and method 1400 (FIG. 14) may be identical or similar to components of the same name used in describing preceding FIGS. 1-8, 9A-9B, and 10-11. In one or more embodiments, an assembly controller of an automated control system or a similar computing device provides the described functionality of method 1200 (FIG. 12), method 1300 (FIG. 13), and method 1400 (FIG. 14).

With reference to FIG. 12A, in one or more embodiments, method 1200 optionally includes obtaining or manufacturing a cold plate made of a thermally conductive material (e.g., copper), the cold plate having an exterior second surface with an array of extended fins (block 1202). In one or more embodiments, method 1200 may include manufacturing the cold plate with a volumetric fluid cavity on a first (base) surface opposed to the second surface with the array of extended fins (block 1204). Method 1200 may include adding a saturated working fluid to the fluid cavity of the cold plate and sealing the fluid cavity to provide thermal energy transfer from a heated first surface by evaporation and condensation of the saturated working fluid to a second surface juxtaposed to the base (first) surface of the cold plate (block 1206). In one or more embodiments, method 1200 includes obtaining or manufacturing a swirl enhancement plate having at least one nozzle opening and having a plurality of swirl enhancement protrusions (block 1208).

The at least one nozzle opening is configured to channel one or more corresponding impingement jets of cooling liquid toward the second surface of the cold plate. Each swirl enhancement protrusion is configured to extend toward the second surface in a corresponding microchannel between two adjacent extended fins of the array of extended fins. The swirl enhancement protrusions induce swirl or turbulence to cooling liquid flow between the adjacent extended fins. The swirl or turbulence disrupts a thermal boundary layer of the cooling liquid flow, resulting in increased liquid heat transfer at the second surface by inducing swirl or turbulence into the cooling liquid flow. In one or more embodiments, the swirl enhancing protrusions are distally tapered to create a larger space between extended fins proximate to the second surface to enable particles in the cooling liquid flow to pass through the extended fins and around the swirl enhancing protrusions. In one or more particular embodiments, the distal taper of the swirl enhancing protrusions are located at least 800 microns from each adjacent extended fin and the encapsulating lid is configured to maintain a flow velocity of the liquid flow to at least 0.7 m/s to prevent sedimentation within the array of extended fins. In one or more particular embodiments, each of the swirl enhancement protrusions have a noncircular geometric shape configured to increase convection heat transfer performance.

In one or more embodiments, method 1200 may include manufacturing the swirl enhancement plate from metal (block 1210). Manufacturing the swirl enhancement plate from metal may precede additional hardening operations such as described below in method 1300 of FIG. 13. With continuing reference to FIG. 12, in one or more alternative embodiments, method 1200 may include manufacturing the swirl enhancement plate via injection molding of a plastic using a silicon mold (block 1212). The plastic may have material characteristic(s) that are one or more of hydrophobic, non-conductive, and anti-corrosive to enable use of facility-grade cooling liquid as a cooling liquid. Then, method 1200 proceeds to block 1214 of FIG. 12B.

With reference to FIG. 12B, method 1200 includes positioning the swirl enhancement plate as a first layer proximate and parallel to a second surface of a cold plate opposite to a first surface of the cold plate attachable to a heat generating electronic component (block 1214). Method 1200 includes sealably attaching an encapsulating lid to the second surface of the cold plate to form a sealed liquid cooling cavity encompassing at least the array of extended fins and the swirl enhancement plate (block 1216). The encapsulating lid includes an intake port sealably coupled to an intake conduit for liquid transfer to the at least one nozzle opening of the swirl enhancement plate; and (ii) an exhaust port sealably coupled to a peripheral outlet conduit positioned to receive heated coolant liquid that has flowed across the second surface of the cold plate. Sealably attaching the encapsulating lid to the cold plate may include use of one or more of a press-fit interference attachment, adhering with an adhesive or adhesive layer, soldering, brazing, welding, and fastener attachment. The encapsulating lid forms a liquid cooling cavity and includes an intake port and an exhaust port for coupling (for supply and return) to a facility liquid source.

With the cold plate assembly completed, method 1200 may optionally include positioning a 2D vapor chamber between the heat generating electronic component and the first surface of the cold plate prior to attaching the heat generating electronic component to the first surface of the cold plate (block 1218). Method 1200 includes attaching the heat generating electronic component of an information processing system to the first surface of the cold plate (or to the bottom surface of the included vapor chamber) for heat transfer away from the heat generating electronic component to the second surface of the cold plate (block 1220). The 2D vapor chamber, if included, is interposed between the heat generating electronic component and the cold plate. The 2D vapor chamber laterally distributes and evens out thermal energy. As compared to lateral dimensions, the 2D vapor chamber may be relatively thin and thus is referred herein as “2D”. The 2D vapor chamber does include sufficient vertical space to facilitate lateral distribution and vertical transfer of thermal energy. The resulting heat generating electronic component can then be liquid cooled during operation by attaching a first conduit from a liquid supply to the intake port and a second conduit from the exhaust port to a rack manifold or facility liquid return (block 1222). Then, method 1200 ends.

In one or more embodiments, the cold plate is manufactured by utilizing copper as the thermally conductive material. The first surface of the cold plate is a heat receiving surface for attaching to a heat generating electronic component directly, or indirectly through an attached vapor chamber. The second surface of the cold plate is a heat transfer surface. In one or more embodiments, in manufacturing the cold plate, method 1200 further includes configuring the fin stack with the levels of fins spaced apart at least 800-microns to facilitate passage of the facility liquid particulates. In one or more embodiments, in manufacturing the encapsulating lid of the cold plate assembly, method 1200 further includes configuring the intake port, exhaust port, and volumetric space of the liquid cooling cavity to maintain a flow velocity of at least 0.7 m/s of liquid impinging the fin stack to prevent sedimentation.

With reference to FIG. 13, method 1300 may further include applying a coating of at least one of a hydrophobic, a non-conductive and an anti-corrosive surface treatment to one or more of wetted surfaces of the cold plate assembly (e.g., cold plate, swirl enhancement plate, and encapsulating lid) for environmentally hardening of the surfaces to reduce corrosion, scaling, and sedimentation to be resistant to chemical impurities and particulates within unpurified cooling liquid (block 1302). In an example, method 1300 includes applying a coating of a hydrophobic surface treatment to the one or more of the wetted surfaces that may be exposed to cooling liquid (block 1304). In another example, method 1300 includes applying a coating of a non-conductive surface treatment to the one or more of the wetted surfaces that may be exposed to cooling liquid (block 1306). In an additional example, method 1300 includes applying a coating of an anti-corrosive surface treatment to the one or more of the wetted surfaces that may be exposed to cooling liquid (block 1308). The coating protects the surface material and thereby allows direct use of facility liquid or facility-grade liquid that may contain corrosive chemical or clogging particulates. With the use of environmentally hardened or coated cold plate assembly (100), isolating the facility liquid in a separate cooling loop from a secondary coolant loop that directly cools the heat generating component is not required. The facility liquid provides direct liquid transfer of heat from a heat generating component to which the cold plate is attached. The coating avoids or mitigates corrosion and clogging of the cold plate due to facility liquid chemicals and/or particulates. Then, method 1300 ends.

In one or more embodiments, as presented in blocks 1304, 1306, and 1308, applying the coating may include only one of the three characteristics (i.e., hydrophobic, non-conductive, and anti-corrosive) in a coating, two of the three characteristics in the coating, or all three of the characteristics in a coating. In one or more embodiments, as presented in blocks 1304, 1306, and 1308, applying the coating may further include coating the one or more of the wetted surfaces that may be exposed to cooling liquid with more than one coating of surface treatment, each coating providing one or more of the three characteristics. In one or more embodiments, as presented in block 1304, coating the one or more of the wetted surfaces that may be exposed to cooling liquid includes applying a hydrophobic layer to prevent scaling and sedimentation due to dissolved calcium carbonate in the facility liquid. In one or more embodiments, method 1300 further includes coating the one or more of the wetted surfaces that may be exposed to cooling liquid using physical vapor deposition (PVD). In one or more embodiments, method 1300 further includes coating the one or more of the wetted surfaces that may be exposed to cooling liquid, via PVD, with one or more ceramics from among a group comprising Zirconium Nitride and Titanium Nitride.

With reference to FIG. 14, method 1400 includes sealably coupling a supply port of an encapsulating lid of the cold plate directly (or indirectly through a supply manifold) to a cooling liquid source of unheated facility liquid (block 1402). Method 1400 includes sealably coupling a return port of the encapsulating lid directly (or indirectly through a return manifold) to a facility return to exhaust heated facility liquid from the cold plate (block 1404). Method 1400 includes activating a supply valve to cause the flow of facility liquid through the cold plate, which receives the unheated facility liquid to provide liquid based cooling of a heat generating electronic component attached to the cold plate and directs the heated facility liquid back to the cooling liquid source or to a cooling liquid return (block 1406). Then, method 1400 ends.

Aspects of the present innovation are described above with reference to flowchart illustrations and/or block diagrams of methods, apparatus (systems) and computer program products according to embodiments of the innovation. It will be understood that each block of the flowchart illustrations and/or block diagrams, and combinations of blocks in the flowchart illustrations and/or block diagrams, can be implemented by computer program instructions. These computer program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

As will be appreciated by one skilled in the art, embodiments of the present innovation may be embodied as a system, device, and/or method. Accordingly, embodiments of the present innovation may take the form of an entirely hardware embodiment or an embodiment combining software and hardware embodiments that may all generally be referred to herein as a “component”, “circuit,” “module” or “system.”

While the innovation has been described with reference to exemplary embodiments, it will be understood by those skilled in the art that various changes may be made, and equivalents may be substituted for elements thereof without departing from the scope of the innovation. In addition, many modifications may be made to adapt a particular system, device, or component thereof to the teachings of the innovation without departing from the essential scope thereof. Therefore, it is intended that the innovation not be limited to the particular embodiments disclosed for carrying out this innovation, but that the innovation will include all embodiments falling within the scope of the appended claims. Moreover, the use of the terms first, second, etc. do not denote any order or importance, but rather the terms first, second, etc. are used to distinguish one element from another.

The terminology used herein is for the purpose of describing particular embodiments only and is not intended to be limiting of the innovation. As used herein, the singular forms “a”, “an” and “the” are intended to include the plural forms as well, unless the context clearly indicates otherwise. It will be further understood that the terms “comprise” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present innovation has been presented for purposes of illustration and description but is not intended to be exhaustive or limited to the innovation in the form disclosed. Many modifications and variations will be apparent to those of ordinary skill in the art without departing from the scope and spirit of the innovation. The embodiments were chosen and described in order to best explain the principles of the innovation and the practical application, and to enable others of ordinary skill in the art to understand the innovation for various embodiments with various modifications as are suited to the particular use contemplated.

What is claimed is:

1. A cold plate assembly comprising:
a cold plate comprising a thermally conductive material and having a first surface attachable to a heat generating electronic component and a second surface opposite to the first surface, the second surface comprising an array of extended fins;
a swirl enhancement plate positioned as a first layer proximate and parallel to the second surface, having at least one nozzle opening to channel one or more corresponding impingement jets of cooling liquid toward the second surface, and having a plurality of swirl enhancement protrusions each extending toward the second surface in a corresponding microchannel between two adjacent extended fins of the array of extended fins to induce the swirl or turbulence to cooling liquid flow between the adjacent extended fins, which disrupts a thermal boundary layer of the cooling liquid flow, resulting in increased liquid heat transfer at the second surface by inducing swirl or turbulence into the cooling liquid flow; and
an encapsulating lid attachable to the second surface to form a liquid cooling cavity encompassing the array of extended fins and swirl enhancement plate and comprising: (i) an intake port for receiving the cooling liquid flow from a cooling liquid source; and (ii) an exhaust port for receiving and expelling exhaust cooling liquid that has flowed across the second surface of the cold plate.

2. The cold plate assembly of claim 1, further comprising a vapor chamber positionable between the first surface of the cold plate and the heat generating electronic component.

3. The cold plate assembly of claim 1, wherein the swirl enhancing protrusions distally taper to create a larger space between extended fins proximate to the second surface to enable particles in the cooling liquid flow to pass through the extended fins and the swirl enhancing protrusions.

4. The cold plate assembly of claim 3, wherein distal taper of the swirl enhancing protrusions are located at least 800 microns from each adjacent extended fin and the encapsulating lid is configured to maintain a flow velocity of the liquid flow to at least 0.7 m/s to prevent sedimentation within the array of extended fins.

5. The cold plate assembly of claim 3, wherein each of the swirl enhancement protrusions comprises a noncircular geometric shape configured to increase convection heat transfer performance.

6. The cold plate assembly of claim 1, wherein the thermally conductive material of the cold plate comprises copper.

7. The cold plate assembly of claim 1, wherein at least a portion of the second surface of the cold plate and the array of extended fins are coated with at least one material that is one or more of hydrophobic, non-conductive, and anti-corrosive to enable use of facility-grade cooling liquid as a cooling liquid.

8. The cold plate assembly of claim 1, wherein the swirl enhancement plate is composed of at least one of a metal or a plastic material and manufactured via an injection molding process.

9. The cold plate assembly of claim 1, wherein the swirl enhancement plate is composed of a metal, and wetted surfaces of the swirl enhancement plate, including the swirl enhancement protrusions, are coated with at least one material that is one or more of hydrophobic, non-conductive, and anti-corrosive to enable use of facility-grade cooling liquid as a cooling liquid.

10. The cold plate assembly of claim 1, wherein the at least one nozzle opening of the swirl enhancement plate comprises an elongate slot orthogonal to the array of extended fins.

11. The cold plate assembly of claim 10, wherein:
the intake port of the encapsulating lid is in fluid connection with an intake fluid cavity that encompasses the at least one nozzle opening; and
the exhaust port of the encapsulating lid is in fluid connection with an outlet fluid cavity that receives cooling liquid flow as exhaust cooling liquid from the array of extended fins and channels the exhaust cooling liquid towards the exhaust port.

12. An information processing system comprising:
at least one heat generating electronic component; and
a cold plate assembly comprising:
a cold plate comprising a thermally conductive material and having a first surface attachable to a heat generating electronic component and a second surface opposite to the first surface, the second surface comprising an array of extended fins;
a swirl enhancement plate positioned as a first layer proximate and parallel to the second surface, having at least one nozzle opening to channel one or more corresponding impingement jets of cooling liquid toward the second surface, and having a plurality of swirl enhancement protrusions each extending toward the second surface in a corresponding microchannel between two adjacent extended fins of the array of extended fins to induce the swirl or turbulence to cooling liquid flow between the adjacent extended fins, which disrupts a thermal boundary layer of the cooling liquid flow, resulting in increased liquid heat transfer at the second surface by inducing swirl or turbulence into the cooling liquid flow; and
an encapsulating lid attachable to the second surface to form a liquid cooling cavity encompassing the array of extended fins and swirl enhancement plate and comprising: (i) an intake port for receiving the cooling liquid flow from a cooling liquid source; and (ii) an exhaust port for receiving and expelling exhaust cooling liquid that has flowed across the second surface of the cold plate.

13. The information processing system of claim 12, wherein the swirl enhancing protrusions distally taper to create a larger space between extended fins proximate to the second surface to enable particles in the cooling liquid flow to pass through the extended fins and the swirl enhancing protrusions.

14. The information processing system of claim 13, wherein distal taper of the swirl enhancing protrusions are located at least 800 microns from each adjacent extended fin and the encapsulating lid is configured to maintain a flow velocity of the liquid flow to at least 0.7 m/s to prevent sedimentation within the array of extended fins.

15. The information processing system of claim 12, wherein each of the swirl enhancement protrusions comprises a noncircular geometric shape configured to increase convection heat transfer performance.

16. The information processing system of claim 12, wherein the thermally conductive material of the cold plate comprises copper.

17. The information processing system of claim 12, wherein at least a portion of the second surface of the cold plate and the array of extended fins are coated with at least one material that is one or more of hydrophobic, non-conductive, and anti-corrosive to enable use of facility-grade cooling liquid as a cooling liquid.

18. The information processing system of claim 12, wherein at least an exterior portion of the swirl enhancement plate comprises at least one material that is one or more of hydrophobic, non-conductive, and anti-corrosive to enable use of facility-grade cooling liquid as a cooling liquid.

19. The information processing system of claim 12, wherein the swirl enhancement plate is composed of at least one of a metal or a plastic material.

20. The information processing system of claim 12, wherein the at least one nozzle opening of the swirl enhancement plate comprises an elongate slot orthogonal to the array of extended fins.

21. The information processing system of claim 20, wherein:
the intake port of the encapsulating lid is in fluid connection with an intake fluid cavity that encompasses the at least one nozzle opening; and
the exhaust port of the encapsulating lid is in fluid connection with an outlet fluid cavity that receives cooling liquid flow as exhaust cooling liquid from the array of extended fins and channels the exhaust cooling liquid towards the exhaust port.

22. The information processing system of claim 12, wherein the cold plate assembly further comprises a vapor chamber positionable between the first surface of the cold plate and the heat generating electronic component.

23. A data center comprising:
an information processing system rack comprising:
an information processing system comprising:
at least one heat generating electronic component; and
a cold plate assembly comprising:
a cold plate comprising a thermally conductive material and having a first surface attachable to a heat generating electronic component and a second surface opposite to the first surface, the second surface comprising an array of extended fins;
a swirl enhancement plate positioned as a first layer proximate and parallel to the second surface, having at least one nozzle opening to channel one or more corresponding impingement jets of cooling liquid toward the second surface, and having a plurality of swirl enhancement protrusions each extending toward the second surface in a corresponding microchannel between two adjacent extended fins of the array of extended fins to induce the swirl or turbulence to cooling liquid flow between the adjacent extended fins, which disrupts a thermal boundary layer of the cooling liquid flow, resulting in increased liquid heat transfer at the second surface by inducing swirl or turbulence into the cooling liquid flow; and
an encapsulating lid attachable to the second surface to form a liquid cooling cavity encompassing the array of extended fins and swirl enhancement plate and comprising: (i) an intake port for receiving the cooling liquid flow from a cooling liquid source; and (ii) an exhaust port for receiving and expelling exhaust cooling liquid that has flowed across the second surface of the cold plate.

24. The data center of claim 23, further comprising:
a facility source of facility cooling liquid, the facility source comprising a facility outlet port and a facility return port; and
a liquid distribution system sealably connected between the intake port of the cold plate assembly and an outlet port of the facility source to channel unheated facility water to the cold plate assembly and between the exhaust port of the cold plate assembly and the facility return port to channel heated exhaust water from the cold plate assembly to the facility return port.

25. The data center of claim 24, wherein the liquid distribution system comprises:
a rack liquid cooling manifold system comprising:
a supply manifold comprising a supply control valve and a manifold intake port available for sealably coupling to a facility water supply to receive a cooling liquid and comprising more than one server supply ports each available for sealably coupling, for liquid transfer of the cooling liquid, to a respective cooling liquid supply input of a corresponding information processing system node supported by a rack frame capable of supporting multiple information processing system nodes, each having one or more heat generating electronic components; and
a return manifold comprising a facility water return port for sealably coupling to a facility return to exhaust the cooling liquid and comprising more than one server return ports, each available for sealably coupling, for exhaust liquid transfer, to a respective cooling liquid exhaust output of the corresponding information processing system node, the respective cooling liquid exhaust output and a paired supply liquid cooling input directing cooling liquid flow through one or more cold plate assembly positioned within the corresponding information processing system node to thermally cool the one or more heat generating electronic components.

26. The data center of claim 25, wherein the liquid distribution system further comprises a plurality of conduits that sealably couple for liquid transfer: (i) the more than one server supply ports of the supply manifold to the corresponding server supply inputs of the more than one information processing system nodes; (ii) the corresponding server supply input to the one or more cold plate assemblies in the corresponding information processing system node; (iii) the one or more cold plate assemblies in the corresponding information processing system node to the corresponding server return output; and (iv) and the more than one server return outputs to the server return ports of the return manifold.

27. The data center of claim 23, wherein the cold plate assembly further comprises a vapor chamber positionable between the first surface of the cold plate and the heat generating electronic component.

28. A method of manufacturing a cold plate assembly for providing liquid cooling of heat generating electronic components, the method comprising:
obtaining a swirl enhancement plate;
positioning the swirl enhancement plate as a first layer proximate and parallel to a second surface of a cold plate, the swirl enhancement plate having at least one nozzle opening to channel one or more corresponding impingement jets of cooling liquid toward the second surface, and having a plurality of swirl enhancement protrusions each extending toward the second surface in a corresponding microchannel between two adjacent extended fins of an array of extended fins to induce the swirl or turbulence to cooling liquid flow between the adjacent extended fins, which disrupts a thermal boundary layer of the cooling liquid flow, resulting in increased liquid heat transfer at the second surface by inducing swirl or turbulence into the cooling liquid flow, the cold plate comprising a thermally conductive material, having a first surface opposite to the second surface and attachable to a heat generating electronic component of an information processing system; and
attaching an encapsulating lid to the second surface to encompass to form a liquid cooling cavity encompassing at least the array of extended fins and the swirl enhancement plate, the encapsulating lid comprising: (i) an intake port sealably coupled to an intake conduit for liquid transfer to the at least one nozzle opening of the swirl enhancement plate; and (ii) an exhaust port sealably coupled to a peripheral outlet conduit positioned to receive heated coolant liquid that has flowed across the second surface of the cold plate.

29. The method of claim 28, wherein obtaining the swirl enhancement plate comprises manufacturing the swirl enhancement plate having the swirl enhancing protrusions distally tapered to create a larger space between extended fins proximate to the second surface to enable particles in the liquid flow to pass through the extended fins and the swirl enhancing protrusions.

30. The method of claim 29, wherein a distal taper of the swirl enhancing protrusions are spaced apart at least 800 microns from one extended fin and the encapsulating lid is configured to maintain a flow velocity of at least 0.7 m/s of the liquid flow to prevent sedimentation within the array of extended fins.

31. The method of claim 29, wherein manufacturing the swirl enhancement plate comprises manufacturing each of the swirl enhancement protrusions with a noncircular geometric shape configured to increase convection heat transfer performance.

32. The method of claim 28, wherein the thermally conductive material of the cold plate comprises copper and the method further comprises coating at least a portion of the second surface of the cold plate and the array of extended fins and wetted surfaces of the swirl enhancement plate with at least one material that is one or more of hydrophobic, non-conductive, and anti-corrosive to enable use of facility-grade cooling liquid as a cooling liquid.

33. The method of claim 32, further comprising using physical vapor deposition to coat the at least the portion of the second surface of the cold plate and the array of extended fins with the at least one material.

34. The method of claim 28, further comprising attaching the heat generating electronic component to the first surface of the cold plate.

35. The method of claim 34, further comprising positioning a vapor chamber between the first surface of the cold plate and the heat generating electronic component, prior to attaching the heat generating electronic component to the first surface of the cold plate.

36. The method of claim 28, wherein obtaining the swirl enhancement plate comprises manufacturing the swirl enhancement plate via injection molding.

37. The method of claim 36, further comprising manufacturing the swirl enhancement plate via injection molding utilizing at least one of a metal or a plastic material within a silicon mold.

38. The method of claim 36, further comprising coating wetted surfaces of the swirl enhancement plate with at least one material that is one or more of hydrophobic, non-conductive, and anti-corrosive to enable use of facility-grade cooling liquid as a cooling liquid.

39. The method of claim 36, wherein the swirl enhancement plate is made of metal and the method further comprises using physical vapor deposition to coat a wetted surfaces of the swirl enhancement plate with the at least one material.

40. The method of claim 36, further comprising manufacturing the swirl enhancement plate using at least one material that is one or more of hydrophobic, non-conductive, and anti-corrosive to enable use of facility-grade cooling liquid as a cooling liquid.
